(19) United States
(12) Patent Application Publication
(10) Pub. No.: US 2012/0156817 A1
(43) Pub. Date: Jun. 21, 2012

(54) Method for Manufacturing High-quality Organic Light-emitting Diode

(75) Inventors: Jwo-Huei Jou, Hsinchu (TW); Sun-Zen Chen, Dongshan Township (TW)

(73) Assignee: NATIONAL TSING-HUA UNIVERSITY, Hsinchu (TW)

(21) Appl. No.: 13/170,904

(22) Filed: Jun. 28, 2011

(30) Foreign Application Priority Data
Dec. 15, 2010 (TW) 099143990

(51) Int. Cl. H01L 51/56

(52) U.S. Cl. 438/35; 257/E51.022

(57) ABSTRACT

The present invention discloses a method for manufacturing a high-quality organic light-emitting diode (OLED), and the method comprises the steps of: providing a substrate; providing at least one template engraved with a pattern; putting at least one organic light-emitting material onto the pattern of the template by an inking process; transferring the organic light-emitting material from the pattern of the template to the substrate by a contact printing process; forming at least one organic light-emitting layer on the substrate, wherein the organic light-emitting layer comprises a plurality of pixels which are arranged in a side by side manner with a complementary emission spectrum, so that the OLED possesses the property of high color rendering, color temperature tunable, or the combination thereof.

### BACKGROUND OF THE INVENTION

1. Field of the Invention

The present invention relates to a method for manufacturing a high-quality organic light-emitting diode (OLED), and more particularly to a method for manufacturing a high-quality OLED with a contact printing process for transferring organic light-emitting materials and then forming at least one organic light-emitting layer composed of a plurality of pixels which are arranged in a side by side manner.

2. Description of the Prior Art

An organic electro-luminescence display (Organic EL Display), also known as an organic light emitting diode (OLED), was invented by C. W. Tang and S. A. VanSlyk et al. of Eastman Kodak Company in 1987 and manufactured by a vacuum evaporation method. A hole transporting material and an electron counterpart are respectively deposited on a transparent indium tin oxide (abbreviated as ITO) glass, and then a metal electrode is vapor-deposited thereon to form the self-luminescent OLED apparatus. Due to high brightness, fast response speed, light weight, compactness, full color, no difference in viewing angles, no need of liquid crystal backlight plate as well as a saving in light source, and low power consumption, it has become a new generation display candidate. Also, it shows great potential for being a promising lighting tool.

Referring to FIG. 1, a cross-sectional diagram of a conventional structure of an OLED apparatus is illustrated. The conventional OLED apparatus A sequentially includes, from the bottom to the top, a transparent substrate A1, a transparent anode (indium tin oxide, ITO) A2, a hole transporting layer (HTL) A3, an organic emissive layer (EL) A4, an electron transporting layer (ETL) A5, an electron injection layer (EIL) A6, and a metal cathode A7. When a forward bias is applied, holes are injected from the anode A2 and electrons are injected from the cathode A7. Due to the potential difference resulted from the external electric field, the electrons and holes move in the thin film and hence recombine in the organic emissive layer A4. A part of the energy released by the recombination of the electron and hole pairs excites the emissive molecules from a ground-state to an excited-state in the organic emissive layer A4. As the emissive molecules fall back form the excited-state to the ground state, a certain portion of the energy is released to emit light.

A color rendering index (CRI) is an important index for evaluating the color quality of an artificial light source. The CRI means the relative difference between the revealed colors of an object illuminated by an artificial light source and the revealed colors of the object illuminated by a sunbeam. The lower value of the CRI, the more differences between the above revealed colors, and the colors presented by the artificial light source is less fidelity. In contrast, the higher value of the CRI, the better color rendering of the artificial light source, that it, the colors presented by the artificial light source lose are close to those presented by the sunbeam.

In order to increase the color rendering of the OLED device, most conventional techniques combine a plurality of OLED devices and regulate some parameters, such as color temperature and wavelength, to achieve high color rendering. Referring to FIG. 2, which is a cross-sectional diagram of a conventional full color OLED apparatus. The OLED device B contains a red OLED B2, a green OLED B3, and a blue OLED B4 which are disposed on a substrate B1. However, because that the above OLED device B should combine a plurality of OLEDs with different light colors for achieving high color rendering, it not only takes more cost but also can increase the volume of the product.

Referring to FIG. 3, which is a cross-sectional diagram of a further conventional full color OLED apparatus. The OLED device C contains a plurality of organic light-emitting layers C4 and C5 which are disposed between a substrate C1, an anode C2 and a cathode C3, wherein the plurality of organic light-emitting layers C4 and C5 contain organic light-emitting dyes having the property of complementary emission spectrum, so that the OLED device C has high color rendering. However, owing to the stacked structure includes more layers, the manufacturing cost and the complexity may be increased. Besides, it is not an easy case for making the plurality of organic light-emitting layers C4 and C5 emit at the same time by accurately controlling the thickness of light-emitting layers and optimizing the device structure. Thus, a traditional method for manufacturing this kind of device has the shortcomings of complicate processes and higher cost.

In view of this, it is necessary to provide a method for manufacturing a high-quality OLED via a simple and easy process.

### SUMMARY OF THE INVENTION

In view of the above shortcomings of the prior art, the inventor of the present invention resorted to past experience, imagination, and creativity, performed experiments and researches repeatedly, and eventually devised the present invention, a method for manufacturing a high-quality organic light-emitting diode (OLED).

The major objective of the present invention is to provide the method for manufacturing the high-quality OLED, which utilizes a contact printing process for transferring organic light-emitting materials, and the OLED with high color rendering and color temperature tunable can be manufactured via a simple process.

According to the above objective, the present invention provides a method for manufacturing a high-quality OLED comprising the steps of: (1) providing a substrate; (2) providing at least one template engraved with a pattern; (3) putting at least one organic light-emitting material onto the pattern of the template by an inking process; (4) transferring the organic light-emitting material from the pattern of the template to the substrate by a contact printing process; and (5) forming at least one organic light-emitting layer on the substrate, wherein the organic light-emitting layer comprises a plurality of pixels which are arranged with a side by side manner and have a property of complementary emission spectrum, so that the OLED possesses the property of high color rendering, color temperature tunable, or the combination thereof.

### BRIEF DESCRIPTION OF THE DRAWINGS

For a complete understanding of the aspects, structures and techniques of the invention, reference should be made to the following detailed description and accompanying drawings wherein:

FIG. 1 is a cross-sectional diagram of a conventional structure of an OLED apparatus;

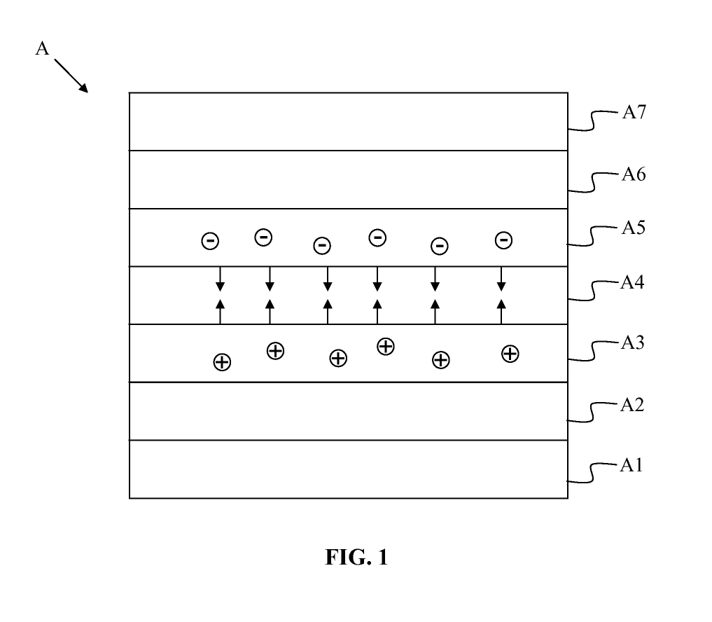

FIG. 2 a cross-sectional diagram of a conventional full color OLED apparatus;

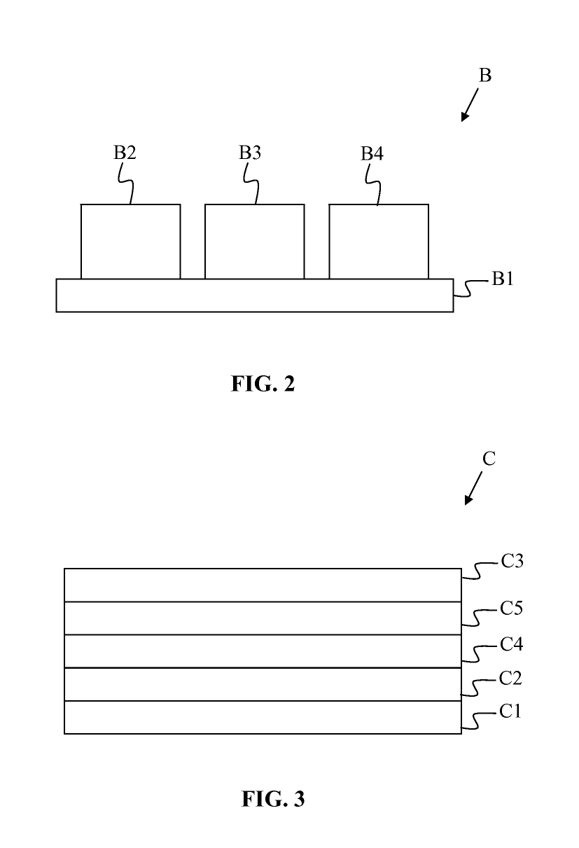

FIG. 3 is a cross-sectional diagram of a further conventional full color OLED apparatus;

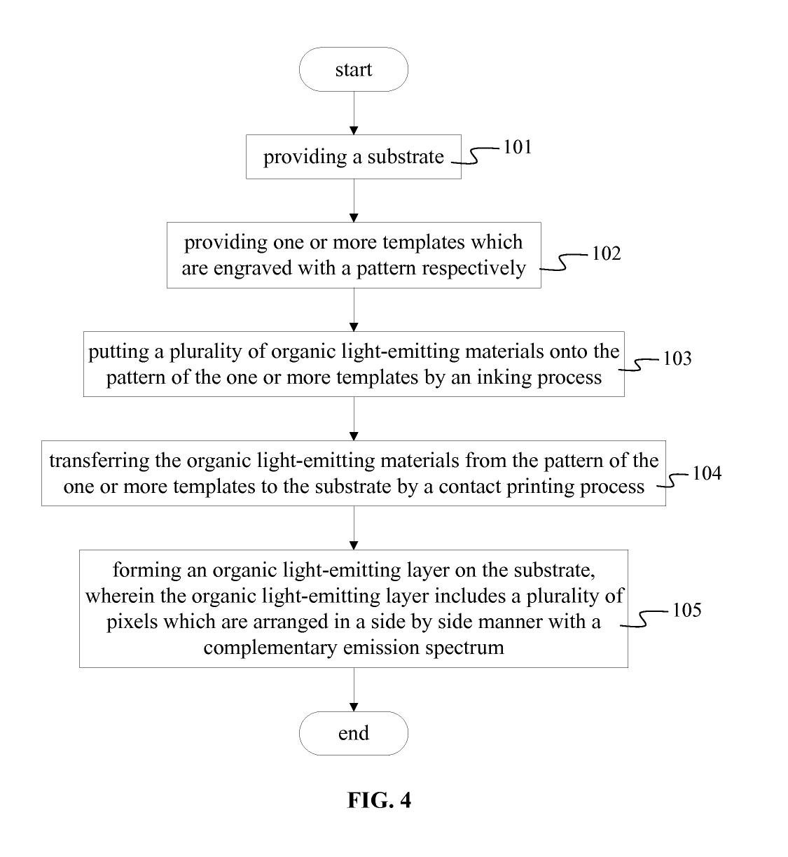

FIG. 4 is a flow chart for manufacturing a high-quality OLED according to a first preferred embodiment of the present invention;

FIG. 5 is a schematic diagram of a template according to the first preferred embodiment of the present invention;

FIG. 6A-FIG. 6E are schematic diagrams of a process for transferring a plurality of organic light-emitting materials to a substrate by a transfer technology according to the first preferred embodiment of the present invention;

FIG. 7 is a schematic diagram of the OLED manufactured by the method according to the first preferred embodiment of the present invention;

FIG. 8A and FIG. 8B are schematic diagrams of two templates according to a second preferred embodiment of the present invention;

FIG. 9 is a flow chart for manufacturing the high-quality OLED according to a third preferred embodiment of the present invention; and

FIG. 10 is a schematic diagram of a template according to the third preferred embodiment of the present invention.

### DETAILED DESCRIPTION OF THE PREFERRED EMBODIMENTS

To achieve the foregoing objectives and effects, the inventors utilize a contact printing process for transferring organic light-emitting materials with single-wavelength spectra or multiple-wavelength spectra which the transferred organic light-emitting layers having pixels arranged in a side by side manner, thus realizing a method for manufacturing a high-quality organic light-emitting diode (OLED) of the present invention. Hereinafter, the method for manufacturing a high-quality OLED according to the following preferred embodiments of the present invention will be described in detail to illustrate the structural features and principles of the present invention.

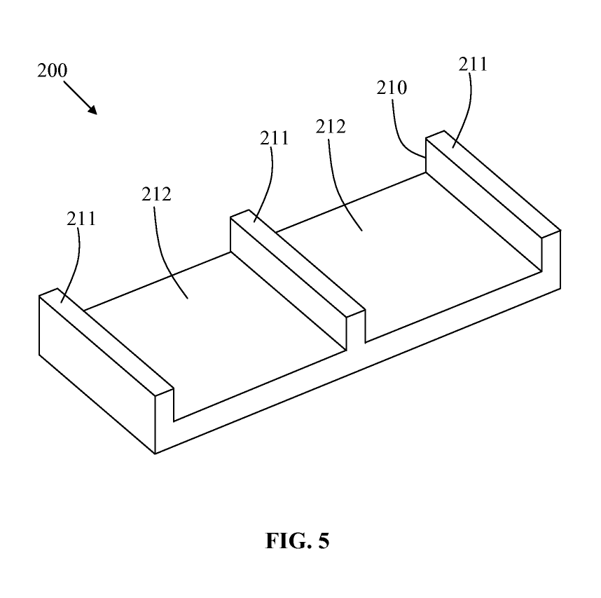

Referring to FIG. 4, which is a flow chart for manufacturing the high-quality OLED according to the first preferred embodiment of the present invention. The method includes the steps of: (step 101) providing a substrate, wherein the substrate can be a rigid material, such as a glass coated with an ITO electrode, or a flexible material, such as a polymer material with a transparent electrode; (step 102) providing one or more templates which are engraved with a pattern respectively, wherein the material of the one or more templates is any available material, such as poly-dimethylsiloxane (PDMS); (step 103) putting a plurality of organic light-emitting materials onto the pattern of the one or more templates by an inking process; (step 104) transferring the organic light-emitting materials from the pattern of the one or more templates to the substrate by a contact printing process, wherein when performing the contact printing process, the transfer efficiency of light-emitting layers can be increased by any process, such as raising the temperature of the substrate or the template by heating, pressurizing the substrate and the template, changing surface properties of the substrate or the template via a surface modification process, or the combination thereof; and (step 105) forming an organic light-emitting layer on the substrate, wherein the organic light-emitting layer includes a plurality of pixels which are arranged in a side by side manner with a complementary emission spectrum, so that the OLED possesses the property of high color rendering, color temperature tunable, or the combination thereof, and wherein the plurality of pixels arranged in the side by side manner can be single-layered structures or multi-layered structures. For the multi-layered structure one, one or more intermediate layer could be disposed between upper and lower layers. The OLED manufactured by the method of the present invention shows the CRI value more than 80, even can reach the ultra high CRI (CRI>90), as well as possesses the property of color temperature tunable.

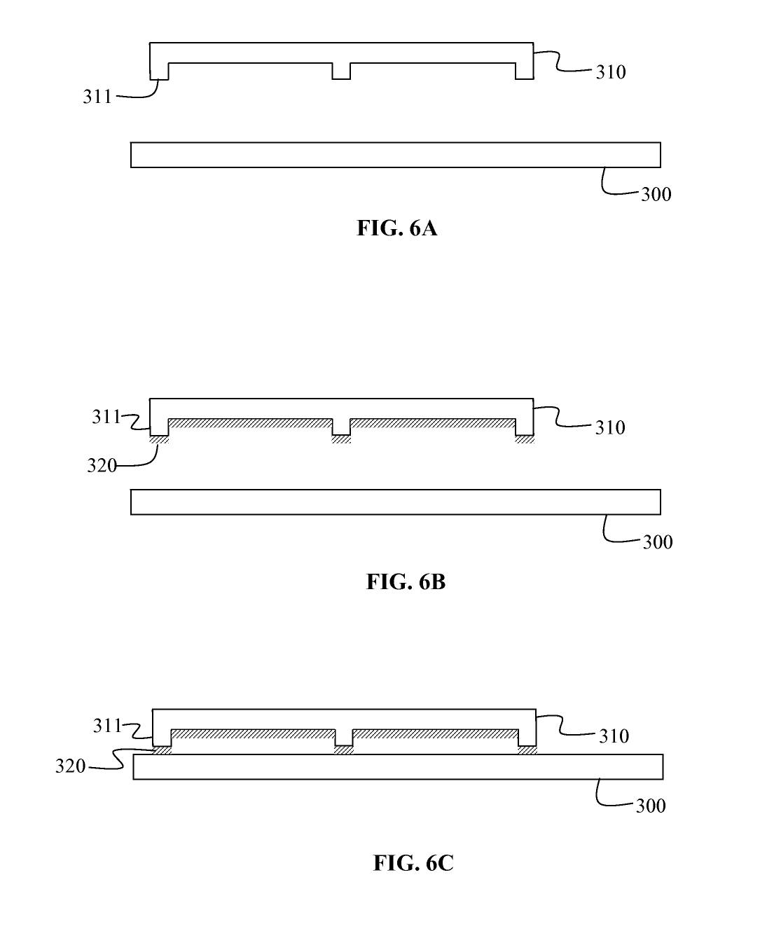

Referring to FIG. 5, which is a schematic diagram of a template according to the first preferred embodiment of the present invention. As shown in the figure, the template 200 is a flat structure, and the pattern 210 is disposed on one plane surface of the template 200. The organic light-emitting materials are adhered to the surface 211 of the protrusive portion of the pattern 210, and then transferred from the surface 211 of the protrusive portion to the substrate. However, when performing the above inking process, the organic light-emitting materials also can be adhered to the valleys 212 of the pattern 210, wherein the organic light-emitting materials adhered to the valleys 212 will not affect the following transfer process if the depth of the valleys 212 are designed appropriately. Furthermore, although the figure illustrates three protrusive portions, the number of the protrusive portions can be increased or decreased according to actual situation.

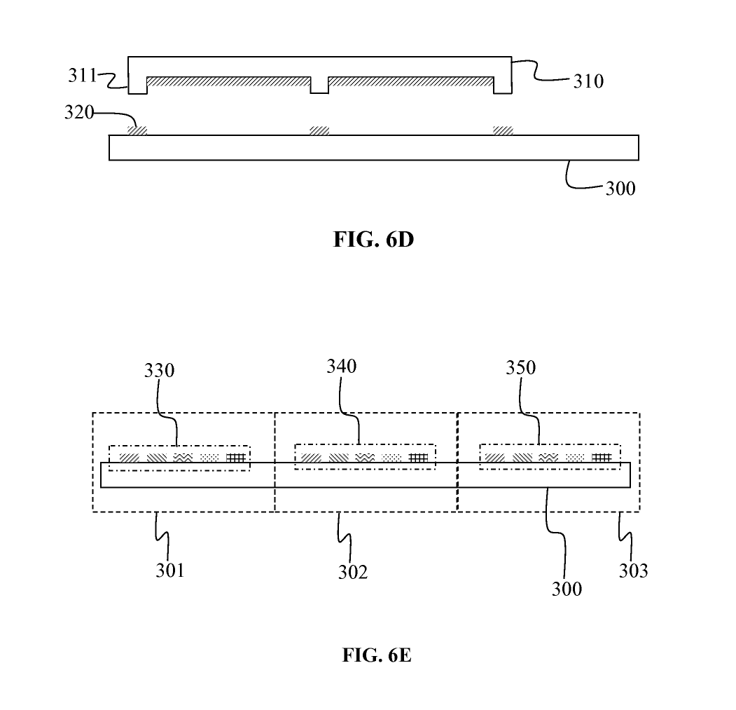

Referring to FIG. 6A to FIG. 6E, schematic diagrams of a process for transferring a plurality of organic light-emitting materials to a substrate by a transfer technology according to the first preferred embodiment of the present invention are illustrated. In FIG. 6A, a substrate 300 and a template 310 are provided, wherein the pattern 311 on the template 310 includes three protrusive portions, in practice, the number of the protrusive portion can be increased or decreased according to different conditions. As shown in FIG. 6B, an organic light-emitting material 320 is adhered to the pattern 311 of the template 310 by the inking process. As shown in FIG. 6C, the organic light-emitting material 320 adhered on the surface of the protrusive portion is transferred onto the substrate 300 by the contact printing process which makes the protrusive portion of the template 310 contact with the substrate 300, and the template 310 and the substrate 300 are pressurized for increasing the transfer efficiency. As shown in FIG. 6D, separating the template 310 from the substrate 300, and the organic light-emitting material 320 is transferred from the template 310 onto the substrate 300. Finally, as shown in FIG. 6E, after repeating the above steps for several times, a plurality of organic light-emitting materials can be transferred to the substrate 300, so as to form an organic light-emitting layer. In FIG. 6E, there are three blocks of organic light-emitting layers 330, 340 and 350, which can exist in one OLED simultaneously to increase the total lighting lamination; or the substrate also can be cut into three parts 301, 302 and 303 by a cutting process, wherein each part 301, 302 and 303 contains a block of organic light-emitting layer 330, 340 and 350, respectively. With this method, a plurality of OLEDs can be manufactured at the same time. Additionally, via the contact printing process of the present invention, each block of organic light-emitting layers 330, 340 or 350 contains a plurality of pixels which are arranged in a side by side manner, and the process of the present invention is simpler and more time-saving than that of traditionally complicate yellow light process and stack process.

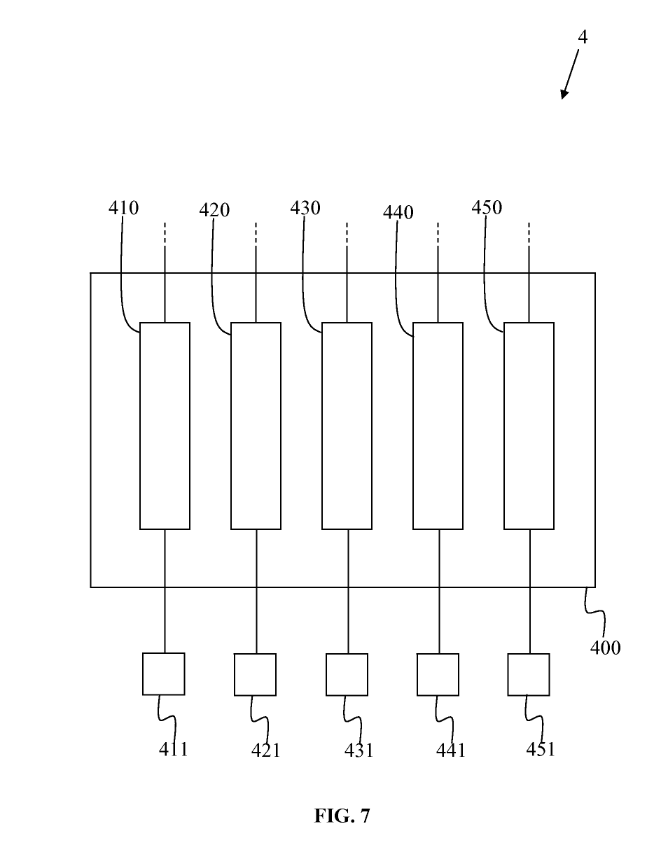

Referring to FIG. 7, which is a schematic diagram of the OLED manufactured by the method according to the first preferred embodiment of the present invention. The OLED 4 contains five pixels arranged in a side by side manner, and the five pixels are formed on the substrate 400 and include a red pixel 410, a green pixel 420, a blue pixel 430, an orange pixel 440, and a yellow pixel 450. However, in practice, the number and the kind of color (such as adding an indigo pixel and a purple pixel) of the pixels are not limited by the first preferred embodiment; the plurality of pixels can be applied in the present invention as long as they have the property of complementary emission spectrum (or the sum of the spectra of the pixels much approaches the solar spectrum), so as to achieve the high color rendering. Furthermore, as shown in figure, each pixel 410, 420, 430, 440, and 450 can be controlled by independent circuit 411, 421, 431, 441, and 451 respectively, wherein the plurality of control circuits 411, 421, 431, 441, and 451 can individually control the switch of the plurality of pixels 410, 420, 430, 440, and 450 arranged in the side by side manner and their lighting intensity, so as to achieve the tuning of color temperatures. For example, the voltages of all the pixels can be increased at the same time to enhance the total lighting intensity of the OLED 4. For another example, one or several of the pixels can be selectively turned off for changing the emitting color and the color temperature of the OLED 4.

Additionally, the above-mentioned plurality of pixels can include a white pixel and at least one monochromatic pixel, wherein the white pixel is composed of a single-layered white light emitting layer or a multi-layered white light emitting layer, and at least one intermediate layer is provided and disposed between the white light emitting layers for the multi-layered one according to requirements.

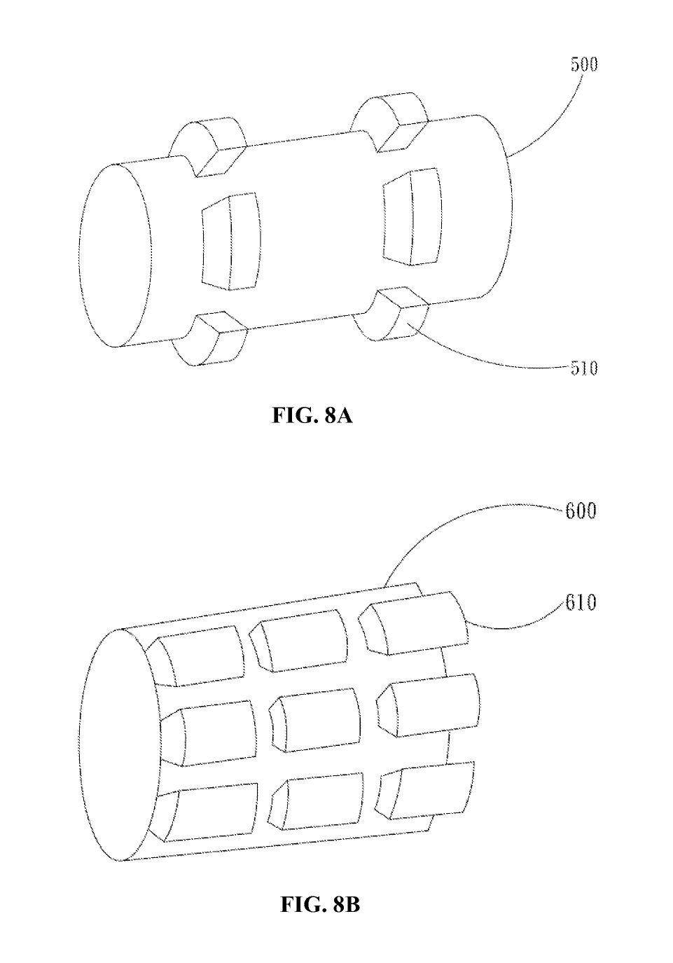

Next, a second preferred embodiment of the present invention is introduced in detail. The process of the method of the second preferred embodiment of the present invention is substantially the same as that of the first preferred embodiment of the present invention and thus will not be described here. The difference between the two preferred embodiments is that the template used in the second preferred embodiment is a wheel structure. Referring to FIG. 8A and FIG. 8B, schematic diagrams of two templates according to the second preferred embodiment of the present invention are illustrated. As shown in the two figures, the templates 500 and 600 are both wheel structures, and the patterns 510 and 610 are disposed on the surfaces of the templates 500 and 600 respectively. The patterns 510 in FIG. 8A (presented as the protrusive portions) are disposed along the circumferential direction of the template 500, and the template 500 performs the contact printing process by a roll-to-roll process, so as to transfer the organic light-emitting materials from the template 500 to the substrate continuously. The patterns 610 in FIG. 8B are axially disposed on the surface of the template 600, and the template 600 also performs the contact printing process by a roll-to-roll process, so as to transfer pixels with specific lengths to the template, and the spacing of the pixels can be regulated according to situation.

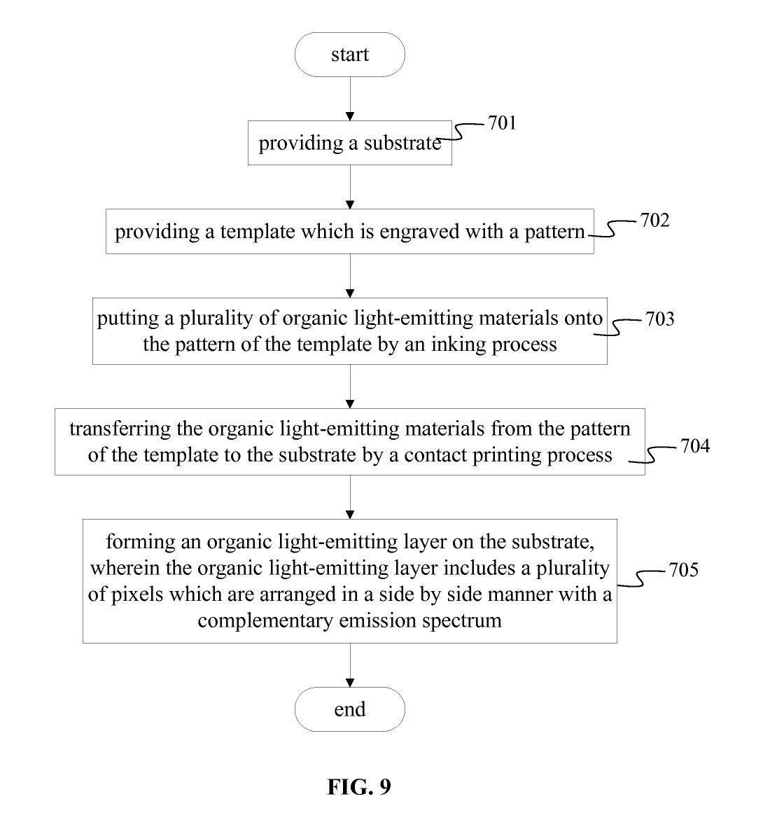

Next, a third preferred embodiment of the present invention is introduced in detail. Referring to FIG. 9, which is a flow chart for manufacturing the high-quality OLED according to a third preferred embodiment of the present invention. The method includes the steps of: (step 701) providing a substrate, wherein the substrate can be a rigid material, such as a glass, or a flexible material, such as a polymer material; (step 702) providing a template which is engraved with a pattern, wherein the template is PDMS; (step 703) putting a plurality of organic light-emitting materials onto the pattern of the template by an inking process, wherein each kind of the organic light-emitting materials is at the surface of different protrusive portions of the pattern respectively; (step 704) transferring the organic light-emitting materials from the pattern of the template to the substrate by a contact printing process, wherein when performing the contact printing process, the transfer efficiency can be increased by any process, such as raising the temperature of the substrate or the template by heating, pressurizing the substrate and the template, changing surface properties of the substrate or the template via a surface modification process, or the combination thereof; and (step 705) forming an organic light-emitting layer on the substrate, wherein the organic light-emitting layer includes a plurality of pixels which are arranged in a side by side manner with a complementary emission spectrum, so that the OLED possesses the property of high color rendering, color temperature tunable, or the combination thereof. The OLED manufactured by the method of the present invention has the CRI value more than 80, even can reach the CRI value of more than 90, thus the OLED conforms the standard of ultra high CRI.

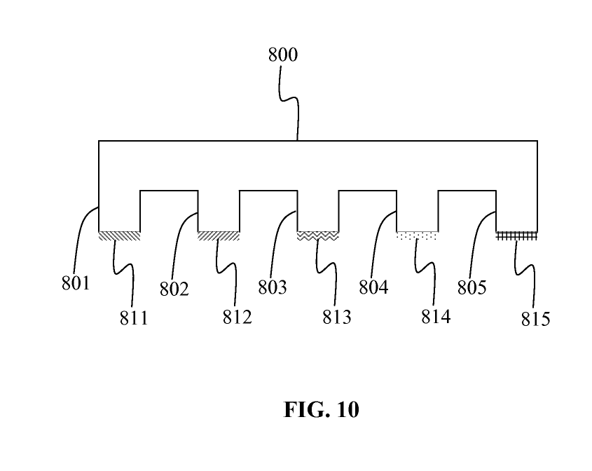

From the above steps, the third preferred embodiment differs from the first and the second preferred embodiments in that the third preferred embodiment inks a plurality kinds of organic light-emitting materials onto one template at the same time, and it does not require a plurality of templates for performing the transfer process. Referring to FIG. 10, which is a schematic diagram of a template according to the third preferred embodiment of the present invention. As shown in the figure, the template 800 has five protrusive portions 801-805, and five kinds of organic light-emitting materials 811-815 are adhered to the surfaces of the five protrusive portions 801-805 respectively by the inking process, and then the five kinds of organic light-emitting materials 811-815 are transferred to the substrate by the contact printing process simultaneously. By this method, five kinds of pixels can be transferred in one step, so as to reduce the manufacturing time. Moreover, the template 800 illustrated in FIG. 10 is a flat structure, however, in practice, the template with a wheel structure also can reach this purpose.

A fourth preferred embodiment of the present invention is introduced in detail. The process of the method of the fourth preferred embodiment of the present invention is substantially the same as that of the first preferred embodiment of the present invention and thus will not be described here. The difference between the two preferred embodiments is that the organic light-emitting materials used in the fourth preferred embodiment is composed of a red pixel, a yellow pixel, a blue pixel, a green pixel, and a white pixel.

A fifth preferred embodiment of the present invention is introduced in detail. The process of the method of the fifth preferred embodiment of the present invention is substantially the same as that of the first preferred embodiment of the present invention and thus will not be described here. The difference between the two preferred embodiments is that the organic light-emitting dyes used in the fifth preferred embodiment is composed of a red pixel, an orange pixel, a yellow pixel, a green pixel, a blue pixel, an indigo pixel, and a purple pixel, that is seven pixels are arranged with a side by side manner in a single area.

A sixth preferred embodiment of the present invention is introduced in detail. The process of the method of the sixth preferred embodiment of the present invention is substantially the same as that of the fourth preferred embodiment of the present invention and thus will not be described here. The difference between the two preferred embodiments is that the white pixel in the sixth preferred embodiment is composed of two white light-emitting layers.

By the detailed description of the overall structure and technical content of the present invention, the following advantages of the present invention can be derived:

Via the contact printing process provided by the present invention for transferring the organic light-emitting dyes, the OLED possessing the properties of high color rendering and color temperature tunable can be manufactured by a simple process.
The present invention can produce the OLED containing the pixels arranged in a side by side manner by a simple process, the cost or the difficulty of the process can be reduced greatly, and thus the present invention has the value of broad application and promotion.
The contact printing process of the present invention can be applied in several kinds of templates and transfer processes, and different contact printing processes can be used according to different conditions, thus the present invention possesses very high process flexibility.

It should be understood that the embodiments of the present invention described herein are merely illustrative of the technical concepts and features of the present invention and are not meant to limit the scope of the invention. Those skilled in the art, after reading the present disclosure, will know how to practice the invention. Various variations or modifications can be made without departing from the spirit of the invention. All such equivalent variations and modifications are intended to be included within the scope of the invention.

As a result of continued thinking about the invention and modifications, the inventors finally work out the designs of the present invention that has many advantages as described above. The present invention meets the requirements for an invention patent, and the application for a patent is duly filed accordingly. It is expected that the invention could be examined at an early date and granted so as to protect the rights of the inventors.

What is claimed is:

1. A method for manufacturing a high-quality organic light-emitting diode (OLED) comprising the steps of:
(1) providing a substrate;
(2) providing at least one template engraved with a pattern;
(3) putting at least one organic light-emitting material onto the pattern of the template by an inking process;
(4) transferring the organic light-emitting material from the pattern of the template to the substrate by a contact printing process; and
(5) forming at least one organic light-emitting layer on the substrate, wherein the organic light-emitting layer comprises a plurality of pixels which are arranged in a side by side manner with a complementary emission spectrum, so that the OLED possesses the property of high color rendering, color temperature tunable, or the combination thereof.

2. The method for manufacturing a high-quality organic light-emitting diode (OLED) according to claim 1, wherein the plurality of pixels in step (5) at least comprises a red pixel, a orange pixel, a yellow pixel, a green pixel, a blue pixel, an indigo pixel, a purple pixel and a combination of thereof.

3. The method for manufacturing a high-quality organic light-emitting diode (OLED) according to claim 1, wherein the plurality of pixels in step (5) comprises a white pixel and at least one monochromatic pixel.

4. The method for manufacturing a high-quality organic light-emitting diode (OLED) according to claim 3, wherein the white pixel is composed of a single-layered white light emitting layer or a multi-layered white light emitting layer.

5. The method for manufacturing a high-quality organic light-emitting diode (OLED) according to claim 4, wherein at least one intermediate layer is provided and disposed between the white light emitting layers for the multi-layered one.

6. The method for manufacturing a high-quality organic light-emitting diode (OLED) according to claim 1, wherein the plurality of pixels arranged in the side by side manner can be single-layered structures or multi-layered structures, and at least one intermediate layer being provided and disposed between upper and lower layers for the multi-layered one.

7. The method for manufacturing a high-quality organic light-emitting diode (OLED) according to claim 1, wherein the plurality of pixels arranged in the side by side manner can be controlled by independent circuit respectively, and the plurality of control circuits being able to individually control the switch of the plurality of pixels arranged in the side by side manner and their lighting intensity.

8. The method for manufacturing a high-quality organic light-emitting diode (OLED) according to claim 1, wherein the template is a flat structure, and the pattern being disposed on one plane surface of the template.

9. The method for manufacturing a high-quality organic light-emitting diode (OLED) according to claim 1, wherein the template is a wheel structure, and the pattern being disposed on the surface of the template.

10. The method for manufacturing a high-quality organic light-emitting diode (OLED) according to claim 9, wherein the contact printing process for the template is a roll-to-roll manner, and the organic light-emitting material being able to be transferred from the template to the substrate continuously.

11. The method for manufacturing a high-quality organic light-emitting diode (OLED) according to claim 1, wherein the material of the substrate is selected from the group consisting of: a rigid material and a flexible material.

12. The method for manufacturing a high-quality organic light-emitting diode (OLED) according to claim 1, wherein when performing the contact printing process in step (4), the temperature of the substrate or the template being able to be raised by heating, so as to increase the transfer efficiency.

13. The method for manufacturing a high-quality organic light-emitting diode (OLED) according to claim 1, wherein when performing the contact printing process in step (4), the substrate and the template being able to be pressurized, so as to increase the transfer efficiency.

14. The method for manufacturing a high-quality organic light-emitting diode (OLED) according to claim 1, wherein when performing the contact printing process in step (4), the substrate and the template being able to undergo a surface modification process, so as to increase the transfer efficiency.
